(19) United States
(12) Patent Application Publication
(10) Pub. No.: US 2025/0098176 A1
(43) Pub. Date: Mar. 20, 2025

(54) MAGNETIC MEMORY DEVICE

(71) Applicant: SAMSUNG ELECTRONICS CO., LTD., SUWON-SI (KR)

(72) Inventor: KILHO LEE, Suwon-si (KR)

(21) Appl. No.: 18/608,130

(22) Filed: Mar. 18, 2024

(30) Foreign Application Priority Data
Sep. 19, 2023 (KR) 10-2023-0124676

(51) Int. Cl. H10B 61/00

(52) U.S. Cl. CPC H10B 61/00

(57) ABSTRACT

A magnetic memory device may include conductive lines provided in cell region and peripheral region, a first insulating layer provided in the cell region and the peripheral region, and surrounding the conductive lines, a second insulating layer provided on the first insulating layer in the cell region and the peripheral region, and on top surfaces of the conductive lines, and data storage patterns provided on the second insulating layer in the cell region and electrically connected to corresponding conductive lines of the conductive lines. The second insulating layer in the peripheral region may include first portions on the top surfaces of the conductive lines, and second portions disposed between the first portions. Top surfaces of the first portions may be disposed at a level higher than top surfaces of the second portions.

### CROSS-REFERENCE TO RELATED APPLICATIONS

This patent application claims priority under 35 U.S.C. § 119 to Korean Patent Application No. 10-2023-0124676, filed on Sep. 19, 2023, in the Korean Intellectual Property Office, the entire contents of which are hereby incorporated by reference.

### TECHNICAL FIELD

The present disclosure relates to a semiconductor device, and in particular, to a magnetic memory device including a magnetic tunnel junction (MTJ).

### DISCUSSION OF RELATED ART

Demand for semiconductor memory devices with faster operating speeds and/or lower operating voltages is increasing with the demand for electronic devices with increased speed and/or reduced power consumption increases. A magnetic memory device has been proposed to satisfy these demands. For example, the magnetic memory device may provide technical advantages including high speed and/or non-volatility. Thus, the magnetic memory device is emerging as a next-generation memory device.

In general, the magnetic memory device may include a magnetic tunnel junction (MTJ). The MTJ may include two magnetic layers and an insulating layer interposed therebetween. An electrical resistance of the MTJ may vary depending on magnetization directions of the magnetic layers. For example, the electrical resistance of the MTJ may be higher when magnetization directions of the magnetic layers are anti-parallel to each other as compared to when the magnetization directions of the magnetic layers are parallel to each other. Such a difference in electrical resistance can be used for data storing data in the magnetic memory device.

### SUMMARY

An embodiment of the inventive concept provides a magnetic memory device with an increased integration density and a method of fabricating the same.

An embodiment of the inventive concept provides a method of reducing a failure rate in a fabrication process and a magnetic memory device fabricated thereby.

An embodiment of the inventive concept provides a magnetic memory device with improved electrical characteristics and a method of fabricating the same.

According to an embodiment of the inventive concept, a magnetic memory device may include a plurality of conductive lines provided in a cell region and a peripheral region, a first insulating layer provided in the cell region and the peripheral region, and surrounding the plurality of conductive lines, a second insulating layer provided on the first insulating layer in the cell region and the peripheral region and on top surfaces of the plurality of conductive lines, and a plurality of data storage patterns provided on the second insulating layer in the cell region and electrically connected to corresponding first conductive lines of the plurality of conductive lines. The second insulating layer in the peripheral region may include a plurality of first portions on the top surfaces of corresponding second conductive lines ones of the plurality of conductive lines, and a plurality of second portions between the plurality of first portions. Top surfaces of the plurality of first portions may be disposed at a level higher than top surfaces of the plurality of second portions.

According to an embodiment of the inventive concept, a magnetic memory device may include a substrate including a cell region and a peripheral region, a plurality of conductive lines provided in the cell region and peripheral region of the substrate, a first insulating layer provided on the substrate in the cell region and the peripheral regions region, and surrounding the conductive lines, a second insulating layer disposed on the first insulating layer in the cell region to cover top surfaces of corresponding first conductive lines of the plurality of conductive lines, a plurality of data storage patterns disposed on the second insulating layer in the cell region and electrically connected to the corresponding first conductive lines, a plurality of insulating patterns disposed on the first insulating layer in the peripheral region on top surfaces of corresponding second conductive lines of the plurality of conductive lines, and a peripheral insulating layer disposed on the first insulating layer in the peripheral region and between the plurality of insulating patterns. The peripheral insulating layer may have dielectric constant lower than a dielectric constant of the second insulating layer and a dielectric constant of the plurality of insulating patterns.

According to an embodiment of the inventive concept, a magnetic memory device may include a substrate including a cell region and a peripheral region, a plurality of conductive lines provided in the cell region and peripheral region of the substrate, a first insulating layer provided on the substrate in the cell region and the peripheral region, and surrounding the plurality of conductive lines, a second insulating layer disposed on the first insulating layer in the cell region and the peripheral region to cover top surfaces of the plurality of conductive lines, and a plurality of data storage patterns disposed on the second insulating layer in the cell region and electrically connected to corresponding conductive lines of the plurality of conductive lines. The second insulating layer in the peripheral region may include a first portion covering top surfaces of the conductive lines in the peripheral region, and the first portions may have a crystal structure different from a crystal structure the second insulating layer in the cell region.

### BRIEF DESCRIPTION OF THE DRAWINGS

FIG. 1 is a circuit diagram illustrating a unit memory cell of a magnetic memory device according to an embodiment of the inventive concept.

FIG. 2 is a plan view illustrating a magnetic memory device according to an embodiment of the inventive concept.

FIG. 3 is a sectional view taken along a line A-A′ of FIG. 2 to illustrate a magnetic memory device according to an embodiment of the inventive concept.

FIG. 4A and FIG. 4B are sectional views, each of which illustrates an example of a magnetic tunnel junction pattern of a magnetic memory device according to an embodiment of the inventive concept.

FIG. 5, FIG. 6, FIG. 7, FIG. 8, and FIG. 9 are sectional views taken along the line A-A′ of FIG. 2 to illustrate a method of fabricating a magnetic memory device according to an embodiment of the inventive concept.

FIG. 10 is a sectional view taken along a line A-A′ of FIG. 2 to illustrate a magnetic memory device according to an embodiment of the inventive concept.

FIG. 11, FIG. 12, FIG. 13, and FIG. 14 are sectional views taken along the line A-A′ of FIG. 2 to illustrate a method of fabricating a magnetic memory device according to an embodiment of the inventive concept.

### DETAILED DESCRIPTION

Example embodiments of the inventive concepts will now be described more fully with reference to the accompanying drawings, in which example embodiments are shown.

The inventive concepts may be implemented in various modifications and have various forms, and specific embodiments are illustrated in the drawings and described in detail in the text. It is to be understood, however, that the inventive concepts are not intended to be limited to the particular forms disclosed, but on the contrary, is intended to cover all modifications, equivalents, and alternatives falling within the spirit and scope of the inventive concepts.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In the drawings, the thickness, the ratio, and the dimension of the elements may be exaggerated for effective description of the technical contents.

The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concepts. The singular forms include the plural forms unless the context clearly indicates otherwise.

Terms such as “below”, “lower”, “above”, “upper” or the like, may be used in the description to describe one element's relationship to another element illustrated in the figures. It will be understood that the terms have a relative concept and may be described on the basis of the orientation depicted in the figures.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

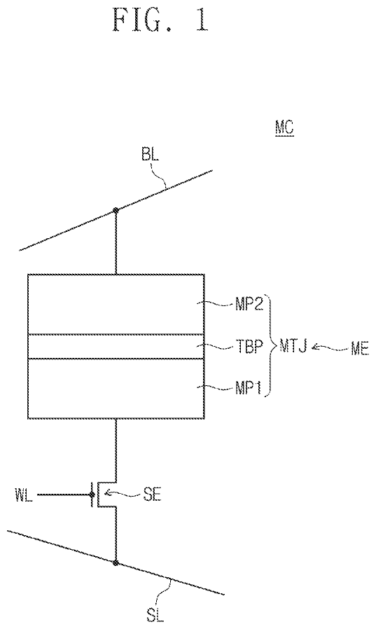

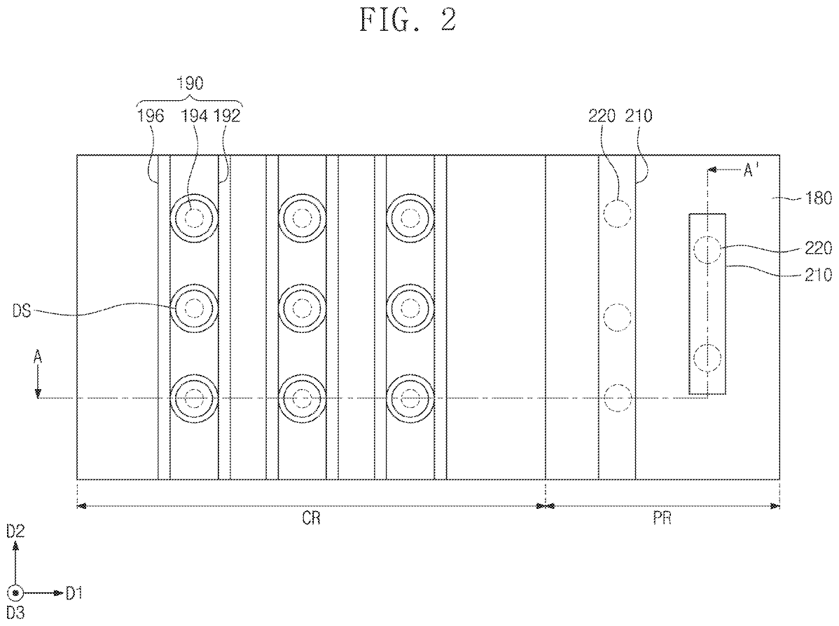

FIG. 1 is a circuit diagram illustrating a unit memory cell of a magnetic memory device according to an embodiment of the inventive concept.

Referring to FIG. 1, a unit memory cell MC may include a memory element ME and a selection element SE. The memory element ME and the selection element SE may be electrically connected to each other in series. The memory element ME may be provided between and connected to a bit line BL and the selection element SE. The selection element SE may be provided between and connected to the memory element ME and a source line SL and may be controlled by a word line WL. The selection element SE may include, for example, a bipolar transistor or a metal-oxide-semiconductor (MOS) field effect transistor.

The memory element ME may include a magnetic tunnel junction MTJ including magnetic patterns MP1 and MP2. The magnetic tunnel junction MTJ including magnetic patterns MP1 and MP2 may be spaced apart from each other, and a tunnel barrier pattern TBP may be interposed between the magnetic patterns MP1 and MP2. A magnetic pattern of the magnetic patterns MP1 and MP2 may have a fixed magnetization direction, regardless of the presence of an external magnetic field generated under a typical user condition, and the magnetic pattern may serve as a reference magnetic pattern of the magnetic tunnel junction MTJ. The other magnetic pattern of the magnetic patterns MP1 and MP2 may have a magnetization direction, which can be changed to one of two stable magnetization directions by an external magnetic field, and may serve as a free magnetic pattern of the magnetic tunnel junction pattern MTJ. The electric resistance of the magnetic tunnel junction MTJ may be greater when magnetization directions of the reference and free magnetic patterns are antiparallel than when they are parallel. In other words, the electric resistance of the magnetic tunnel junction MTJ may be controlled by adjusting the magnetization direction of the free magnetic pattern. Here, a difference in electric resistance of the magnetic tunnel junction MTJ, which is caused by a difference in magnetization direction between the reference and free magnetic patterns, may be used as a mechanism for storing data in the memory element ME or the unit memory cell MC.

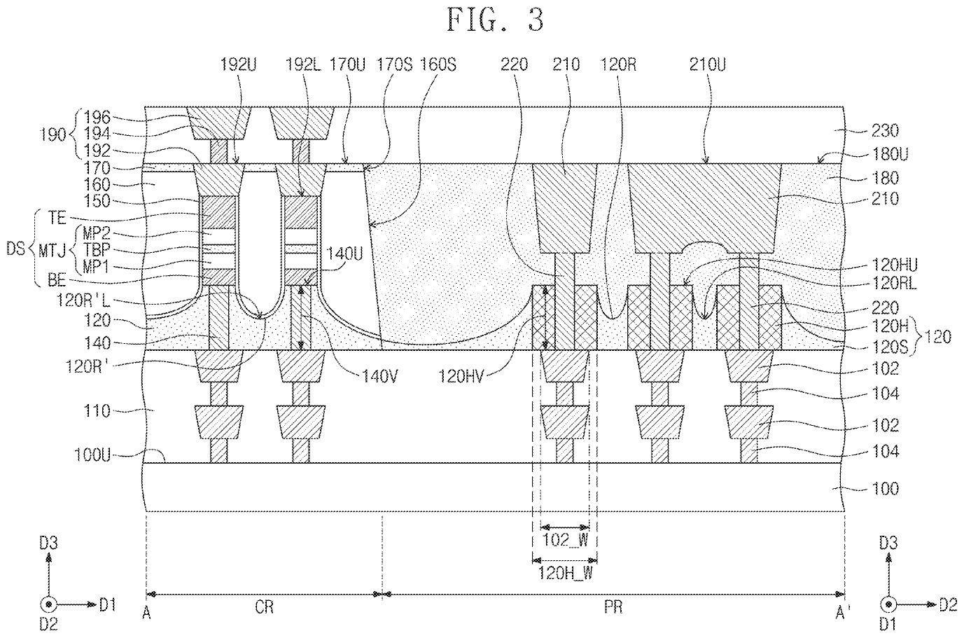

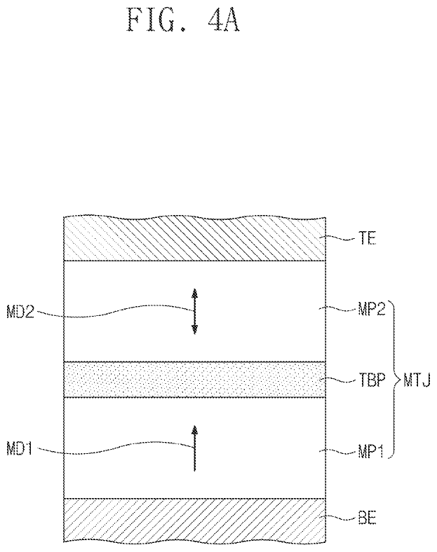

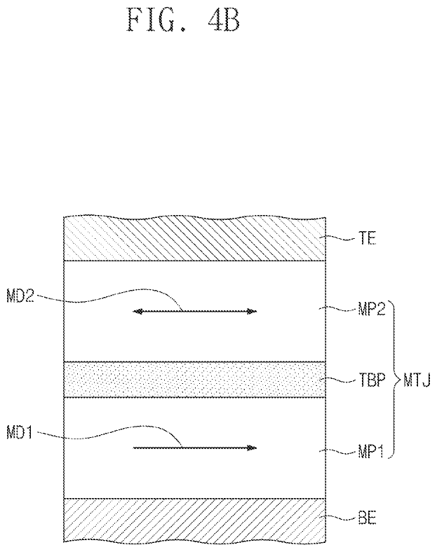

FIG. 2 is a plan view illustrating a magnetic memory device according to an embodiment of the inventive concept. FIG. 3 is a sectional view taken along a line A-A′ of FIG. 2 to illustrate a magnetic memory device according to an embodiment of the inventive concept. FIG. 4A and FIG. 4B are sectional views, each of which illustrates an example of a magnetic tunnel junction pattern of a magnetic memory device according to an embodiment of the inventive concept.

Referring to FIG. 2 and FIG. 3, a substrate 100 including a cell region CR and a peripheral region PR may be provided. The substrate 100 may be a semiconductor substrate, which may be formed of, or includes at least one of silicon (Si), silicon germanium (SiGe), germanium (Ge), or gallium arsenide (GaAs), or may be a silicon-on-insulator (SOI) wafer. The cell region CR may be a region of the substrate 100, on which the memory cells MC of FIG. 1 are located, and the peripheral region PR may be another region of the substrate 100, on which peripheral circuits for driving the memory cells MC are located.

A conductive structure 102/104 may be disposed on the substrate 100. The conductive structure 102/104 may be disposed in the cell region CR and the peripheral region PR of the substrate 100. The conductive structure 102/104 may include conductive lines 102, which may be vertically spaced apart from the substrate 100, and conductive contacts 104, which may be connected to the conductive lines 102. The conductive lines 102 may be spaced apart from a top surface 100U of the substrate 100 in a direction perpendicular to the top surface 100U of the substrate 100. The conductive contacts 104 may be disposed between the substrate 100 and the conductive lines 102. Each of the conductive lines 102 may be electrically connected to the substrate 100 through a corresponding conductive contact of the conductive contacts 104. The conductive lines 102 and the conductive contacts 104 may be formed of, or include one or more metallic materials (e.g., copper).

The selection elements SE of FIG. 1 may be disposed in the cell region CR of the substrate 100, and peripheral transistors constituting the peripheral circuits may be disposed in the peripheral region PR of the substrate 100. In an embodiment, the selection elements and the peripheral transistors may be field effect transistors. Each of the conductive lines 102 may be electrically connected to one terminal (e.g., a source, drain, or gate terminal) of a corresponding one of the selection elements or the peripheral transistors through a corresponding conductive contact of the conductive contacts 104.

A first insulating layer 110 may be disposed on the substrate 100 to cover the conductive structure 102/104. The first insulating layer 110 may be disposed on the substrate 100 to surround the conductive structure 102/104 in the first direction D1 and the second direction D2. The first insulating layer 110 may be disposed in the cell region CR of the substrate 100 and may be extended to the peripheral region PR of the substrate 100. The first insulating layer 110 may be provided to expose top surfaces of the uppermost conductive lines of the conductive lines 102. As an example, a top surface of the first insulating layer 110 may be substantially coplanar with the top surfaces of the uppermost conductive lines 102. The first insulating layer 110 may be formed of, or include at least one of silicon oxide, silicon nitride, and/or silicon oxynitride.

A second insulating layer 120 may be disposed on the first insulating layer 110 and may cover the exposed top surfaces of the uppermost ones of the conductive lines 102. The second insulating layer 120 may be disposed on the first insulating layer 110 in the cell region CR and may extend to a region on the first insulating layer 110 in the peripheral region PR. The second insulating layer 120 may include a material having a carbon nitride (CN) group. More particularly, the second insulating layer 120 may include silicon nitride (e.g., SiCN).

The second insulating layer 120 in the peripheral region PR may include first portions 120H, which may cover top surfaces of the conductive lines 102 in the peripheral region PR, and second portions 120S, which may be provided between the first portions 120H. Top surfaces of the second portions 120S may be located at a level lower than top surfaces of the first portions 120H.

The first portions 120H may cover top surfaces of the conductive lines 102, respectively. A width 120H_W of each of the first portions 120H in the first direction D1 may be larger than or equal to a width 102_W of each of the conductive lines 102 in the first direction D1. Thus, the first portions 120H may completely cover the top surfaces of the conductive lines 102.

Between the first portions 120H, the second portions 120S may have a first recess region 120R, which may be recessed toward the substrate 100. For example, the second portions 120S may have a first recess region 120R in which an upper surface of the second insulating layer 120 may be recessed toward the substrate 100, and may have a level that is lower than a surround portion of the second insulating layer 120. A lowermost portion of a top surface 120RL of the first recess region 120R may be located at a level lower than a top surface 120HU of the first portion 120H.

The first portions 120H may have a crystal structure that is different from the second portions 120S. In detail, the second insulating layer 120 may include a first nonmetal and a second nonmetal, which are different from each other, and a bonding structure of the first and second nonmetals in the first portions 120H may be different from a bonding structure of the first and second nonmetals in the second portions 120S. As an example, the first and second nonmetals may be carbon (C) and nitrogen (N), respectively, and a fraction of a sp³ C—N bonding in the first portions 120H may be greater than a fraction of the sp³ C—N bonding in the second portions 120S. In a case where the fraction of the sp³ C—N bonding in the first portions 120H is greater than the fraction of the sp³ C—N bonding in the second portions 120S, the hardness of the first portions 120H may be greater than that of the second portions 120S. Here, sp³ refers to a sp³ hybridization. For example, in a C(sp³)-N structure, all bonds of the carbon atom may be single bonds.

The first portions 120H may have a crystal structure that is different from the second insulating layer 120 in the cell region CR. In detail, the second insulating layer 120 in the cell region CR may include first and second nonmetals that are different from those in the first portions 120H. Here, a bonding structure of the first and second nonmetals in the first portions 120H may be different from a bonding structure of the first and second nonmetals in the second insulating layer 120 in the cell region CR. As an example, the first and second nonmetals may be carbon and nitrogen, respectively, and the fraction of the sp³ C—N bonding in the first portions 120H may be greater than a fraction of the sp³ C—N bonding in the second insulating layer 120 in the cell region CR. In a case where the fraction of the sp³ C—N bonding in the first portions 120H is greater than the fraction of the sp³ C—N bonding in the second insulating layer 120 in the cell region CR, the first portions 120H may have a hardness that is greater than a hardness of the second insulating layer 120 in the cell region CR.

The second portions 120S may have the same crystal structure as the second insulating layer 120 in the cell region CR. The second portions 120S may include first and second nonmetals that are different from those in the second insulating layer 120 in the cell region CR. Here, the first and second nonmetals in the second portions 120S may be provided to form the same bonding structure as the first and second nonmetals in the second insulating layer 120 in the cell region CR. In an embodiment, the first and second nonmetals may be carbon and nitrogen, respectively, and a bonding structure of carbon and nitrogen in the second portions 120S may be the same as that in the second insulating layer 120 in the cell region CR.

Data storage patterns DS may be disposed on the second insulating layer 120 in the cell region CR. The data storage patterns DS may be spaced apart from each other in the first direction D1 and the second direction D2. The second insulating layer 120 in the cell region CR may have a second recess region 120R′ that is recessed toward the substrate 100 between the data storage patterns DS. For example, the second insulating layer 120 may have a second recess region 120R′ in which an upper surface of the second insulating layer 120 may be recessed toward the substrate 100, and may have a level that is lower than a surround portion of the second insulating layer 120.

Bottom electrode contacts 140 may be disposed in the second insulating layer 120 in the cell region CR and may be spaced apart from each other in the first and second directions D1 and D2. The bottom electrode contacts 140 may be disposed below and electrically connected to the data storage patterns DS, respectively. Each of the bottom electrode contacts 140 may penetrate the second insulating layer 120 in the cell region CR and may be connected to a corresponding first conductive line of the uppermost conductive lines 102. Each of the data storage patterns DS may be electrically connected to a terminal (e.g., a drain terminal) of a corresponding selection element through each of the bottom electrode contacts 140 and a corresponding first conductive line of the uppermost conductive lines 102. A height 140V of the bottom electrode contacts 140 may be equal to a vertical thickness 120HV of the first portions 120H. In a case where the height 140V of the bottom electrode contacts 140 is reduced to the vertical thickness 120HV of the first portions 120H), it may be possible to easily increase an integration density of the magnetic memory device. In the present specification, the term ‘height’ may be a distance that is measured in a third direction D3 perpendicular to the top surface 100U of the substrate 100, and a first direction D1 and a second direction D2 may be parallel to the top surface 100U of the substrate 100 and may not be parallel to each other.

Top surfaces 140U of the bottom electrode contacts 140 may be located at a level higher than a lowermost portion of a top surface 120R′L of the second recess region 120R′ in the cell region CR. The bottom electrode contacts 140 may be formed of, or include at least one of doped semiconductor materials (e.g., doped silicon), metallic materials (e.g., tungsten (W), titanium (Ti), and/or tantalum (Ta)), metal-semiconductor compounds (e.g., metal silicide), or conductive metal nitrides (e.g., titanium nitride, tantalum nitride, and/or tungsten nitride).

Each of the data storage patterns DS may include a bottom electrode BE, a magnetic tunnel junction MTJ, and a top electrode TE, which may be sequentially stacked on the second insulating layer 120 in the third direction D3. For example, the bottom electrode BE may be disposed on the second insulating layer 120, the magnetic tunnel junction MTJ may be disposed on the bottom electrode BE, and the top electrode TE may be disposed on the magnetic tunnel junction MTJ. The magnetic tunnel junction MTJ may be disposed between the bottom electrode BE and the top electrode TE. Each of the bottom electrode contacts 140 may be connected to the bottom electrode BE of each of the data storage patterns DS. The magnetic tunnel junction MTJ may include a first magnetic pattern MP1, a second magnetic pattern MP2, and a tunnel barrier pattern TBP therebetween. The first magnetic pattern MP1 may be disposed between the bottom electrode BE and the tunnel barrier pattern TBP. The second magnetic pattern MP2 may be disposed between the top electrode TE and the tunnel barrier pattern TBP. The bottom electrode BE may be formed of, or include for example, one or more conductive metal nitrides (e.g., titanium nitride or tantalum nitride). The top electrode TE may be formed of, or include at least one of a metallic material (e.g., Ta, W, Ruthenium (Ru), or Iridium (Ir)) or a conductive metal nitride (e.g., TiN).

Referring to FIG. 4A and FIG. 4B, the first magnetic pattern MP1 may be a reference layer whose magnetization direction MD1 is fixed to a specific direction, and the second magnetic pattern MP2 may be a free layer whose magnetization direction MD2 can be changed to be parallel or antiparallel to the magnetization direction MD1 of the first magnetic pattern MP1. FIG. 4A and FIG. 4B illustrate an example, in which the second magnetic pattern MP2 is used as the free layer, but the inventive concept is not limited to this example. For example, the first magnetic pattern MP1 may be the free layer, and the second magnetic pattern MP2 may be the reference layer.

Referring to FIG. 4A, the magnetization directions MD1 and MD2 of the first and second magnetic patterns MP1 and MP2 may be perpendicular to an interface between the tunnel barrier pattern TBP and the second magnetic pattern MP2. In this case, each of the first magnetic pattern MP1 and the second magnetic pattern MP2 may be formed of, or include at least one of intrinsic or extrinsic perpendicular magnetic materials. The intrinsic perpendicular magnetic material may include a material exhibiting a perpendicular magnetization property, even when there is no external influence. The intrinsic perpendicular magnetic material may include at least one of i) perpendicular magnetic materials (e.g., CoFeTb, CoFeGd, or CoFeDy), ii) perpendicular magnetic materials with L1₀ structure, iii) CoPt-based materials with hexagonal-close-packed structure, or iv) perpendicular magnetic structures. The perpendicular magnetic material may include, for example, one or more of cobalt (Co), iron (Fe), terbium (Tb), gadolinium (Gd), or dysprosium (Dy). The perpendicular magnetic material with the L1₀ structure may include at least one of L1₀ FePt, L1₀ FePd, L1₀ CoPd, or L1₀ CoPt. Here, Pt refers to platinum and Pd refers to palladium. The perpendicular magnetic structures may include magnetic and non-magnetic layers that are alternatingly and repeatedly stacked. As an example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where “n” is a natural number equal to or greater than 2. Here, Ni refers to nickel and Cr refers to chromium. The extrinsic perpendicular magnetic material may include a material that may exhibit an intrinsic in-plane magnetization property in the absence of an external influence, and may exhibit a perpendicular magnetization property in the present of, or following, an external influence, such as a bias voltage. For example, due to a magnetic anisotropy, which results from interfacial characteristics between the first or second magnetic pattern MP1 or MP2 and the tunnel barrier pattern TBP, the extrinsic perpendicular magnetic material may have the perpendicular magnetization property. The extrinsic perpendicular magnetic material may be formed of, or include, for example, CoFeB. Here, B refers to boron.

Referring to FIG. 4B, the magnetization directions MD1 and MD2 of the first and second magnetic patterns MP1 and MP2 may be parallel to the interface between the tunnel barrier pattern TBP and the second magnetic pattern MP2. In this case, each of the first and second magnetic patterns MP1 and MP2 may be formed of, or include one or more ferromagnetic material. The first magnetic pattern MP1 may further include an anti-ferromagnetic material, which may be provided in the first magnetic pattern MP1 and may be used to fix a magnetization direction of the ferromagnetic material.

Each of the first magnetic pattern MP1 and the second magnetic pattern MP2 may be formed of, or include one or more Co-containing Heusler alloys. The tunnel barrier pattern TBP may include at least one of, for example, magnesium oxide, titanium oxide, aluminum oxide, magnesium-zinc oxide, or magnesium-boron oxide.

Referring back to FIG. 2 and FIG. 3, a capping insulating layer 150 may be disposed on the second insulating layer 120 in the cell region CR. The capping insulating layer 150 may conformally cover the side surface of each of the data storage patterns DS and the lowermost portion of the top surface 120R′L of the second recess region 120R′ in the cell region CR. The capping insulating layer 150 may enclose the side surface of each of the data storage patterns DS, when viewed in a plan view. The capping insulating layer 150 may conformally cover the side surfaces of the bottom electrode BE, the magnetic tunnel junction MTJ, and the top electrode TE. The capping insulating layer 150 may enclose the side surfaces of the bottom electrode BE, the magnetic tunnel junction MTJ, and the top electrode TE, when viewed in a plan view. The capping insulating layer 150 may be formed of, or include one or more nitride materials (e.g., silicon nitride).

A cell insulating layer 160 may be disposed on the second insulating layer 120 in the cell region CR and may cover the data storage patterns DS. The cell insulating layer 160 may be disposed between the data storage patterns DS. The cell insulating layer 160 may fill a space between the data storage patterns DS. The capping insulating layer 150 may be interposed between the side surface of each of the data storage patterns DS and the cell insulating layer 160. The capping insulating layer 150 may be extended to a region between the second recess region 120R′ in the cell region CR and the cell insulating layer 160. The cell insulating layer 160 may be formed of, or include at least one of silicon oxide, silicon nitride, and/or silicon oxynitride. As an example, the cell insulating layer 160 may be formed of, or include one or more oxide materials (e.g., tetra-ethyl ortho-silicate (TEOS)).

An upper insulating layer 170 may be disposed in the cell region CR and on the cell insulating layer 160. The upper insulating layer 170 may include a material different from the cell insulating layer 160. For example, the upper insulating layer 170 may be formed of, or include silicon nitride (e.g., SiCN).

A peripheral insulating layer 180 may be disposed on the second insulating layer 120 in the peripheral region PR. The peripheral insulating layer 180 may fill the first recess region 120R in the peripheral region PR and may be in contact with the lowermost portion of the top surface 120RL of the first recess region and the top surface 120HU of the first portions 120H. The peripheral insulating layer 180 may be in contact with a side surface 160S of the cell insulating layer 160 and a side surface 170S of the upper insulating layer 170. A top surface 180U of the peripheral insulating layer 180 may be located at the same level as a top surface 170U of the upper insulating layer 170. The top surface 180U of the peripheral insulating layer 180 may be coplanar with the top surface 170U of the upper insulating layer 170.

The peripheral insulating layer 180 may include a material different from the cell insulating layer 160 and the second insulating layer 120. The peripheral insulating layer 180 may be formed of, or include an insulating material that has a dielectric constant (k) lower than the cell insulating layer 160 and the second insulating layer 120. The peripheral insulating layer 180 may include a material different from the upper insulating layer 170, and in an embodiment, it may be formed of, or include an insulating material having a dielectric constant (k) lower than the upper insulating layer 170. The peripheral insulating layer 180 may be formed of, or include at least one of silicon oxide, silicon nitride, and/or silicon oxynitride. As an example, the peripheral insulating layer 180 may include an insulating material (e.g., porous silicon oxycarbide (SiOC)) whose dielectric constant (k) is less than about 2.5 or 2.0. In a case where the first recess region 120R is filled with the peripheral insulating layer 180, which includes an insulating material with a small dielectric constant (k), it may be possible to increase a transfer speed of electric signals in the magnetic memory device. Thus, the magnetic memory device with improved electrical characteristics may be provided.

A first cell conductive line 192 may be disposed in the cell region CR. The first cell conductive lines 192 may be extended in the first direction D1 and may be spaced apart from each other in the second direction D2. Each of the first cell conductive lines 192 may be a line-shaped pattern extending in the first direction D1. Each of the first cell conductive lines 192 may be electrically connected to corresponding ones of the data storage patterns DS, which are spaced apart from each other in the first direction D1. The data storage patterns DS, which are spaced apart from each other in the second direction D2, may be electrically connected to the first cell conductive lines 192, respectively.

Each of the first cell conductive lines 192 may be provided to penetrate the upper insulating layer 170 and an upper portion of the cell insulating layer 160 and may be connected to the corresponding data storage patterns DS, which are spaced apart from each other in the first direction D1. A bottom surface 192L of each of the first cell conductive lines 192 may be in contact with the corresponding data storage patterns DS, which are spaced apart from each other in the first direction D1, and may be in contact with the top electrode TE of each of the corresponding data storage patterns DS, which are spaced apart from each other in the first direction D1. The first cell conductive lines 192 may include a conductive material and may be formed of, or include, for example, a metallic material (e.g., copper).

Peripheral conductive lines 210 may be disposed on the second insulating layer 120, which is disposed in the peripheral region PR, and in the peripheral insulating layer 180. The peripheral insulating layer 180 may cover the peripheral conductive lines 210. Top surfaces 210U of the peripheral conductive lines 210 may not be covered with the peripheral insulating layer 180 and may be exposed to the outside of the peripheral insulating layer 180. The top surfaces 210U of the peripheral conductive lines 210 may be substantially coplanar with the top surface 180U of the peripheral insulating layer 180. The top surfaces 210U of the peripheral conductive lines 210 may be located at the same level as the top surface 180U of the peripheral insulating layer 180. The top surfaces 210U of the peripheral conductive lines 210 may be located at the same level as top surfaces 192U of the first cell conductive lines 192 and a top surface 170U of the upper insulating layer 170. The top surfaces 210U of the peripheral conductive lines 210 may be coplanar with the top surfaces 192U of the first cell conductive lines 192 and the top surface 170U of the upper insulating layer 170.

Peripheral conductive contacts 220 may be disposed in the peripheral region PR and under the peripheral conductive lines 210. The peripheral conductive contacts 220 may be electrically connected to the peripheral conductive lines 210. Each of the peripheral conductive contacts 220 may be in contact with a corresponding peripheral conductive line of the peripheral conductive lines 210 without any interface therebetween. The peripheral conductive contacts 220 and the corresponding peripheral conductive line 210 may be connected to each other to form a single object. Each of the peripheral conductive contacts 220 may be provided to penetrate a lower portion of the peripheral insulating layer 180. In the peripheral region PR, each of the peripheral conductive contacts 220 may be provided to penetrate the first portions 120H of the second insulating layer 120 and may be electrically connected to a corresponding second conductive line of the uppermost conductive lines 102. Each of the peripheral conductive lines 210 may be electrically connected to a terminal (e.g., source, drain and gate terminals) of the corresponding peripheral transistor through the corresponding peripheral conductive contact 220 and the uppermost conductive lines 102.

The peripheral conductive lines 210 and the peripheral conductive contacts 220 may include a conductive material and may be formed of, or include, for example, a metallic material (e.g., copper). The first cell conductive lines 192, the peripheral conductive lines 210, and the peripheral conductive contacts 220 may be formed of, or include the same material.

A first interlayer insulating layer 230 may be disposed in the cell region CR and the peripheral region PR to cover the top surface 170U of the upper insulating layer 170, the top surfaces 192U of the first cell conductive lines 192, the top surface 180U of the peripheral insulating layer 180, and the top surfaces 210U of the peripheral conductive lines 210. The first interlayer insulating layer 230 may be formed of, or include silicon oxide, silicon nitride, and/or silicon oxynitride.

Second cell conductive lines 196 may be disposed in the first interlayer insulating layer 230 in the cell region CR. The second cell conductive lines 196 may be extended in the first direction D1 and may be spaced apart from each other in the second direction D2. The second cell conductive lines 196 may be overlapped with the first cell conductive lines 192, respectively, in a vertical direction (e.g., the third direction D3). First conductive contacts 194 may be disposed in the first interlayer insulating layer 230 in the cell region CR and may be disposed between the first cell conductive lines 192 and the second cell conductive lines 196. Each of the first cell conductive lines 192 may be electrically connected to a corresponding second cell conductive line of the second cell conductive lines 196 through a corresponding first conductive contact of the first conductive contacts 194. The first cell conductive line 192, the first conductive contact 194, and the second cell conductive line 196 may constitute the bit line 190, which corresponds to the bit line BL of FIG. 1. The first conductive contacts 194 and the second cell conductive lines 196 may be formed of, or include at least one of a conductive material or a metallic material (e.g., copper).

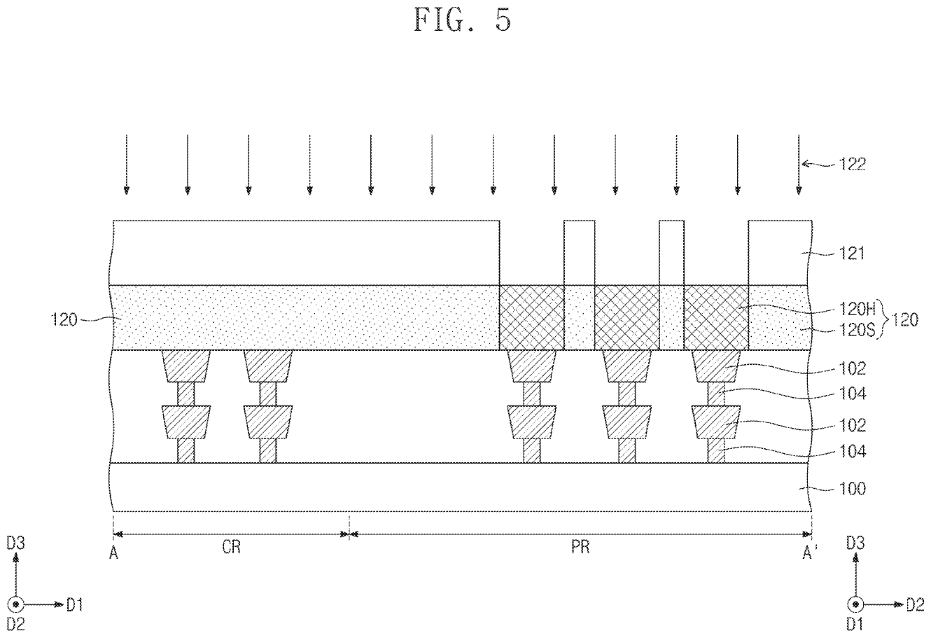

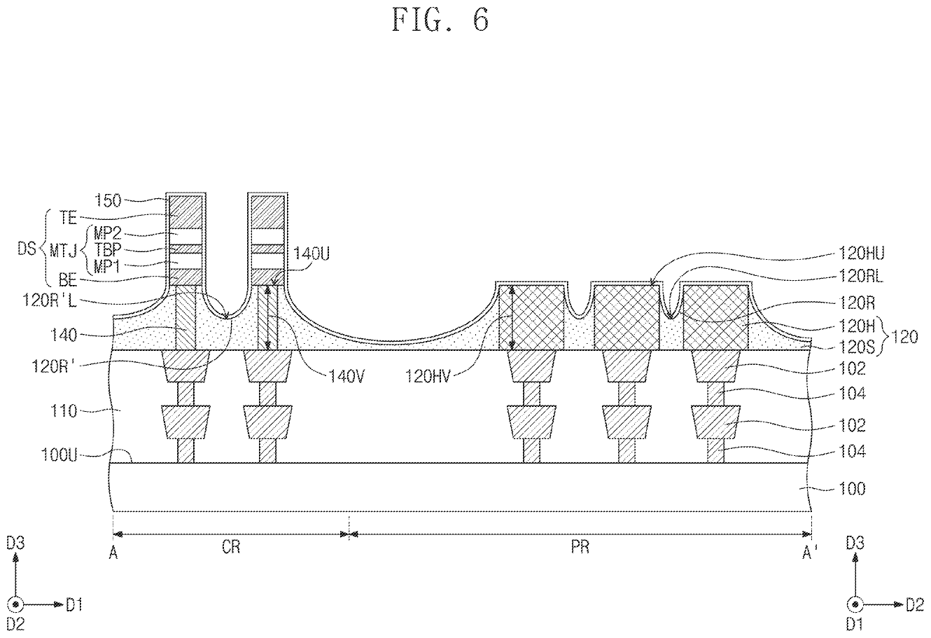

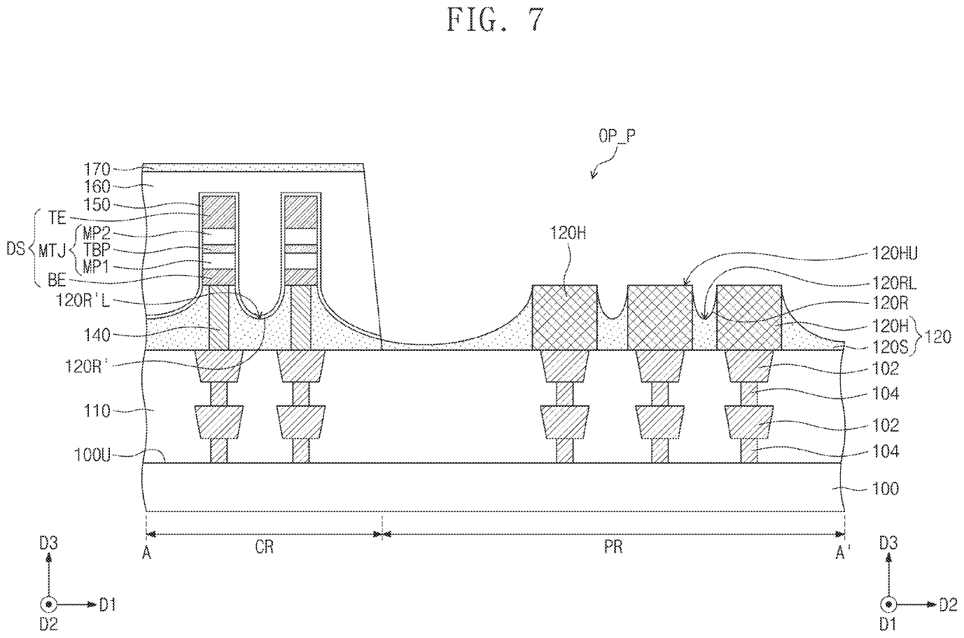

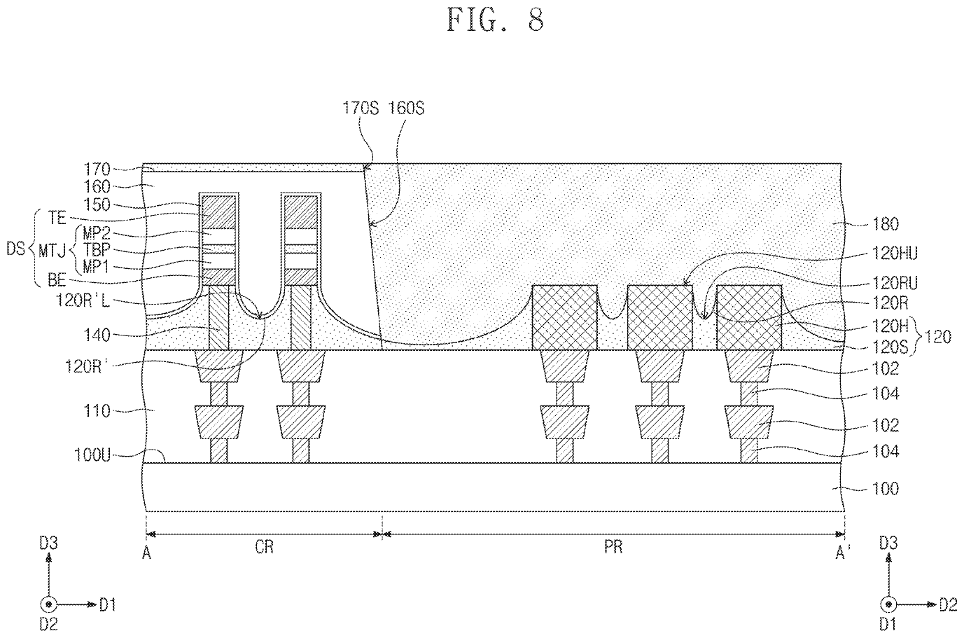

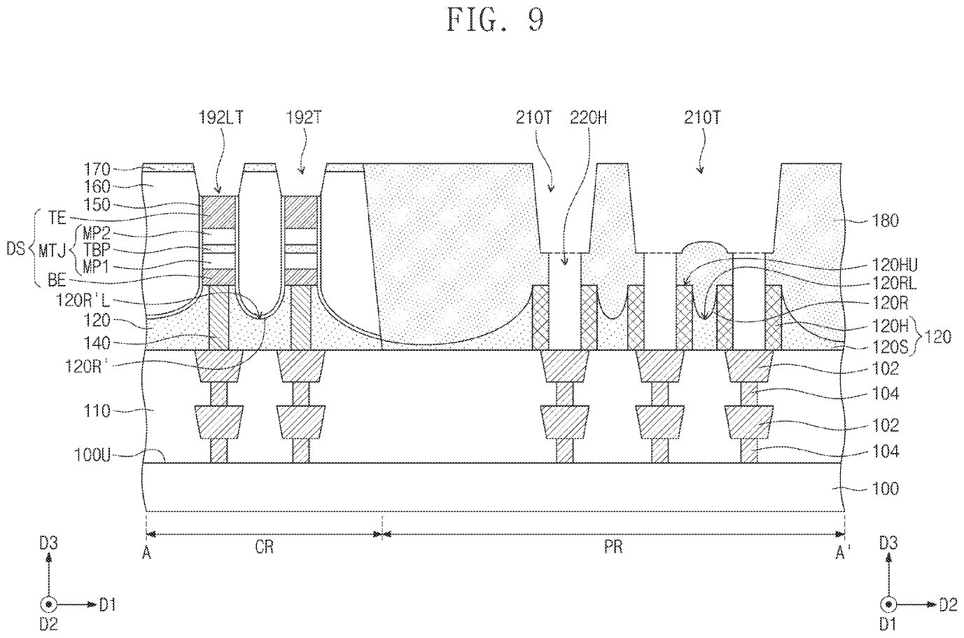

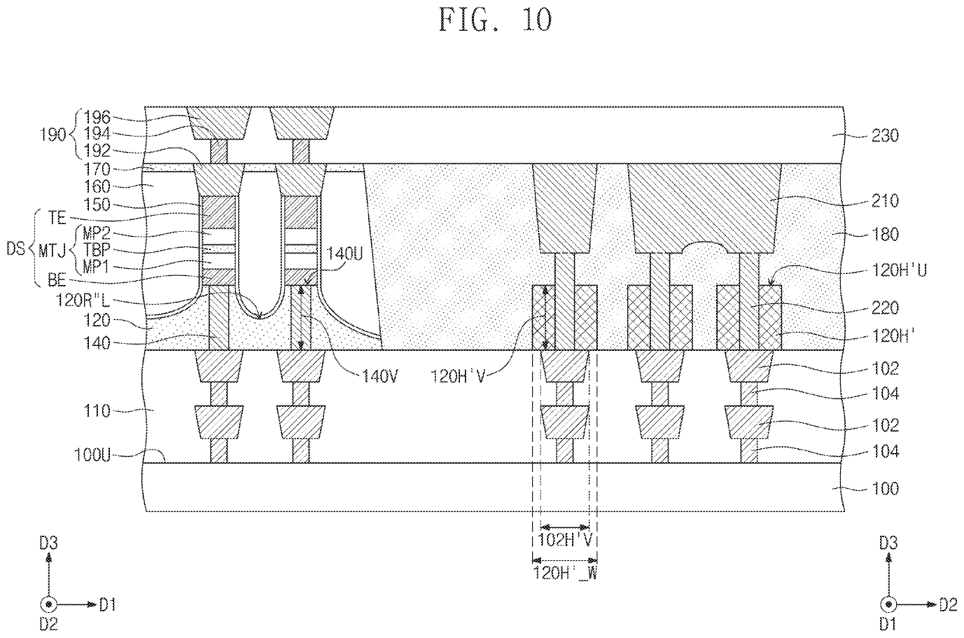

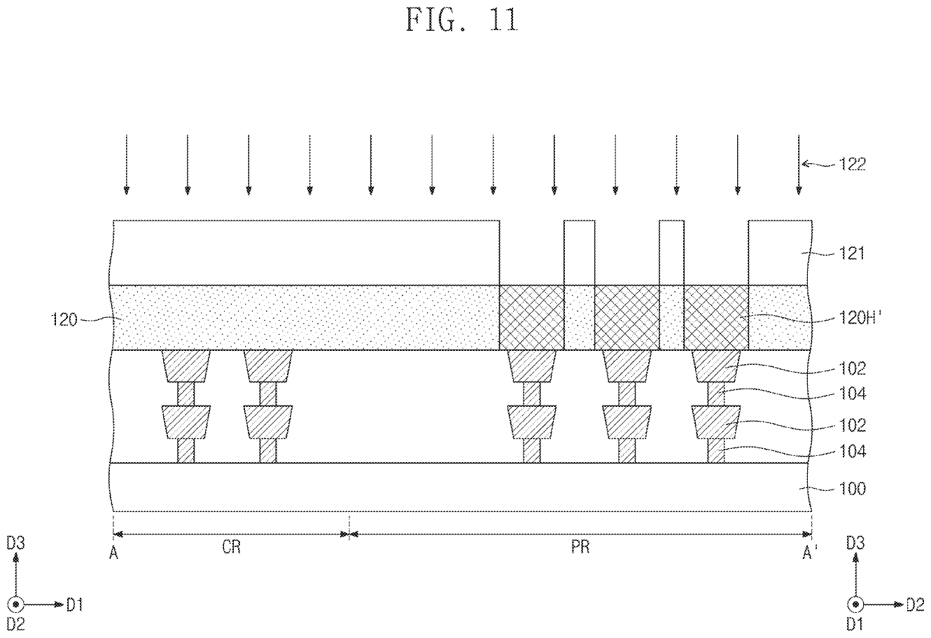

FIG. 5, FIG. 6, FIG. 7, FIG. 8, and FIG. 9 are sectional views taken along the line A-A′ of FIG. 2 to illustrate a method of fabricating a magnetic memory device according to an embodiment of the inventive concept. For concise description, an element previously described with reference to FIG. 1, FIG. 2, FIG. 3, FIG. 4A, and FIG. 4B may be identified by the same reference number without repeating an overlapping description thereof.

Referring to FIG. 2 and FIG. 5, the substrate 100 with the cell and peripheral regions CR and PR may be provided. The selection elements SE (e.g., see FIG. 1) and the peripheral transistors may be formed on the substrate 100, and the conductive structure 102/104 may be formed on the selection elements and the peripheral transistors. The conductive structure 102/104 may include the conductive lines 102, which are spaced apart from the substrate 100 in a vertical direction (e.g., the third direction D3), and the conductive contacts 104, which are connected to the conductive lines 102. Each of the conductive lines 102 may be electrically connected to a terminal (e.g., one of source, drain, and gate terminals) of a corresponding one of the selection elements or the peripheral transistors through a corresponding conductive contact of the conductive contacts 104.

The first insulating layer 110 may be formed on the substrate 100 to cover the conductive structure 102/104. For example, the first insulating layer 110 may be formed on the substrate 100 to surround the conductive structure 102/104 in the first direction D1 and the second direction D2. In an embodiment, the first insulating layer 110 may be formed to expose top surfaces of the uppermost ones of the conductive lines 102.

The second insulating layer 120 may be formed on the first insulating layer 110 to cover the exposed top surfaces of the uppermost conductive lines 102. The second insulating layer 120 may be formed on the first insulating layer 110 in the cell region CR and may be extended to a region on the first insulating layer 110 in the peripheral region PR. In the peripheral region PR, the second insulating layer 120 may include the first portions 120H, which are provided to cover top surfaces of the conductive lines 102 in the peripheral region PR, and the second portions 120S, which are provided between the first portions 120H. The formation of the first portions 120H may include forming a mask pattern 121 on the second insulating layer 120 and irradiating an electron beam 122 onto the mask pattern 121. In an embodiment, the electron beam 122 may be an ion beam or a pulsed electron beam, and the mask pattern 121 may be a photoresist pattern. The electron beam 122 may alter a structure of the first portions 120H. For example, the first portions 120H, which are irradiated with the electron beam 122, may have a crystal structure different from the second portions 120S, which are not irradiated with the electron beam 122. As an example, a fraction of the sp³ C—N bonding in the first portions 120H may be greater than the fraction of the sp³ C—N bonding in the second portions 120S. More particularly, the electron beam 122 may increase the fraction of the sp³ C—N bonding in the first portions 120H, which may increase a hardness of the first portions 120H.

A width 120H_W of the first portions 120H in the first direction D1 may be larger than or equal to a width 102_W in the first direction D1 of the conductive lines 102, and thus, the first portions 120H may fully cover the top surfaces of the conductive line 102. In an embodiment, the electron beam 122 may alter a structure of the first portions 120H. For example, the first portions 120H, which are irradiated with the electron beam 122, may have a crystal structure different from the second insulating layer 120 in the cell region CR, which are not irradiated with the electron beam 122. As an example, the fraction of the sp³ C—N bonding in the first portions 120H may be larger than a fraction of the sp³ C—N bonding in the second insulating layer 120 in the cell region CR. The second portions 120S, which are not irradiated with the electron beam 122, may have the same crystal structure as the second insulating layer 120 in the cell region CR, which are not irradiated with the electron beam 122. As an example, a bonding structure of carbon and nitrogen in the second portions 120S may be the same as that in the second insulating layer 120 in the cell region CR.

Referring to FIG. 2 and FIG. 6, the bottom electrode contacts 140 may be formed in the second insulating layer 120 in the cell region CR, and in an embodiment, each of the bottom electrode contacts 140 may be formed to penetrate the second insulating layer 120 in the cell region CR. The bottom electrode contacts 140 may be electrically connected to a corresponding first conductive line of the uppermost conductive lines 102, and the height 140V of the bottom electrode contacts 140 may be substantially equal to the vertical thickness 120HV of the first portions 120H. In an embodiment, the formation of the bottom electrode contacts 140 may include forming lower contact holes to penetrate the second insulating layers 120 in the cell region CR, forming a lower contact layer on the second insulating layer 120 to fill the lower contact holes, and planarizing the lower contact layer to expose a top surface of the second insulating layer 120. Following the planarization process, the bottom electrode contacts 140 may be locally formed in the lower contact holes, respectively. In addition, following the planarization process, the height 140V of the bottom electrode contacts 140 may be equal to the vertical thickness 120HV of the first portions 120H.

The data storage patterns DS may be formed on the second insulating layer 120 in the cell region CR. The bottom electrode contacts 140 may be disposed below and electrically connected to the data storage patterns DS, respectively.

Each of the data storage patterns DS may include a bottom electrode BE, a magnetic tunnel junction MTJ, and a top electrode TE, which are sequentially stacked on the second insulating layer 120. The magnetic tunnel junction MTJ may include a first magnetic pattern MP1, a second magnetic pattern MP2, and a tunnel barrier pattern TBP therebetween. The first magnetic pattern MP1 may be disposed between the bottom electrode BE and the tunnel barrier pattern TBP, and the second magnetic pattern MP2 may be disposed between the top electrode TE and the tunnel barrier pattern TBP. In an embodiment, the formation of the data storage patterns DS may include sequentially forming a bottom electrode layer and a magnetic tunnel junction layer on the second insulating layer 120, forming a conductive mask pattern on the magnetic tunnel junction layer, and sequentially etching the magnetic tunnel junction layer and the bottom electrode layer using the conductive mask pattern as an etch mask. The magnetic tunnel junction layer may include a first magnetic layer, a tunnel barrier layer, and a second magnetic layer, which are sequentially stacked on the bottom electrode layer. In an embodiment, the magnetic tunnel junction layer and the bottom electrode layer may be formed by a sputtering, chemical vapor deposition, or atomic layer deposition process.

Following the etching of the magnetic tunnel junction layer and the bottom electrode layer, the magnetic tunnel junction MTJ and the bottom electrode BE may be formed, respectively. The etching of the magnetic tunnel junction layer may include sequentially etching the second magnetic layer, the tunnel barrier layer, and the first magnetic layer using the conductive mask pattern as an etch mask. The second magnetic layer, the tunnel barrier layer, and the first magnetic layer may be etched to form the second magnetic pattern MP2, the tunnel barrier pattern TBP, and the first magnetic pattern MP1, respectively. A portion of the conductive mask pattern remaining on the magnetic tunnel junction MTJ after the etching of the magnetic tunnel junction layer and the bottom electrode layer, may be referred to as the top electrode TE.

In an embodiment, the process of etching the magnetic tunnel junction layer and the bottom electrode layer may be an ion beam etching process performed using an ion beam. The ion beam may include inert ions. Following the etching process, the second portions 120S may have the first recess region 120R, which may be recessed toward the substrate 100, between the first portions 120H in the peripheral region PR. The lowermost portion of the top surface 120RL of the first recess region 120R may be located at a level lower than the top surface 120HU of the first portions 120H. In a case where the sp³ C—N bonding fraction of the first portions 120H is greater than that of the second portions 120S, the first portions 120H may have a hardness greater than the second portions 120S. In this case, the first portions 120H may not be etched by the etching process, whereas the second portions 120S may be formed to have the first recess region 120R recessed toward the substrate 100. In a case where the first portions 120H are formed on the top surfaces of the conductive lines 102, it may be possible to protect the conductive lines 102 from damaged by the etching process and to reduce a failure rate in a process of fabricating a magnetic memory device. Furthermore, since the first portions 120H may protect the conductive lines 102 from being damaged by the etching process, the height 140V of the bottom electrode contacts 140 may be reduced to the vertical thickness 120HV of the first portions 120H. Thus, it may be possible to increase an integration density of the magnetic memory device.

In addition, following the etching process, the second insulating layer 120 between the data storage patterns DS may have a second recess region 120R′ that is recessed toward the substrate 100. The lowermost portion of the top surface 120R′L of the second recess region 120R′ may be located at a level lower than the top surfaces 140U of the bottom electrode contacts 140.

A capping insulating layer 150 may be formed on the second insulating layer 120 in the cell region CR to conformally cover top and side surfaces of each of the data storage patterns DS. The capping insulating layer 150 may conformally cover a recessed top surface 120RU of the second insulating layer 120 in the cell region CR and may be extended to cover the top surface 120HU of the first portion 120H and the lowermost portion of the top surface 120RL of the first recess region 120R in the peripheral region PR.

Referring to FIG. 2 and FIG. 7, a cell insulating layer 160 may be formed on the capping insulating layer 150. The cell insulating layer 160 may be formed on the capping insulating layer 150 in the cell region CR to cover the data storage patterns DS and be disposed between the data storage patterns DS. The cell insulating layer 160 may fill a space between the data storage patterns DS. The cell insulating layer 160 may be extended to cover the capping insulating layer 150 in the peripheral region PR. In an embodiment, the cell insulating layer 160 may be formed using a high density plasma chemical vapor deposition (HDP CVD) process.

An upper insulating layer 170 may be formed on the cell insulating layer 160. The upper insulating layer 170 may be formed on the cell insulating layer 160 in the cell region CR and may be extended to cover the cell insulating layer 160 in the peripheral region PR.

A peripheral opening OP_P may be formed in the peripheral region PR to expose the top surface 120HU of the first portion 120H and the lowermost portion of the top surface 120RL of the first recess region 120R. The formation of the peripheral opening OP_P may include removing the upper insulating layer 170, the cell insulating layer 160, and the capping insulating layer 150 from the peripheral region PR. In an embodiment, the formation of the peripheral opening OP_P may include forming a cell mask pattern on the upper insulating layer 170 in the cell region CR and etching the upper insulating layer 170, the cell insulating layer 160, and the capping insulating layer 150 in the peripheral region PR using the cell mask pattern as an etch mask. In an embodiment, the cell mask pattern may be a photoresist pattern. In a case where the upper insulating layer 170, the cell insulating layer 160, and the capping insulating layer 150 are removed from the peripheral region PR, the top surface 120HU of the first portion 120H and the lowermost portion of the top surface 120RL of the first recess region 120R may be exposed to the outside.

Referring to FIG. 2 and FIG. 8, a peripheral insulating layer 180 may be formed to fill the peripheral opening OP_P. The peripheral insulating layer 180 may be in contact with the lowermost portion of the top surface 120RL of the first recess region 120R and the top surface 120HU of the first portions 120H in the peripheral region PR. The peripheral insulating layer 180 may fill the first recess region 120R in the peripheral region PR. The peripheral insulating layer 180 may be in contact with a side surface 160S of the cell insulating layer 160 in the cell region CR and may be in contact with a side surface 170S of the upper insulating layer 170 in the cell region CR.

The peripheral insulating layer 180 may be formed of, or include an insulating material whose dielectric constant may be less than the second insulating layer 120 and the cell insulating layer 160. In an embodiment, the formation of the peripheral insulating layer 180 may include forming an insulating layer to fill the peripheral opening OP_P and planarizing the insulating layer to expose a top surface of the upper insulating layer 170. In an embodiment, the insulating layer may be formed using a chemical vapor deposition process. The planarization process may be performed using at least one of an etch-back process or a chemical mechanical polishing process.

Referring to FIG. 2 and FIG. 9, first cell trenches 192T may be formed in the cell region CR. The first cell trenches 192T may be spaced apart from each other in the first direction D1. Each of the first cell trenches 192T may expose corresponding ones of the data storage patterns DS, which are spaced apart from each other in the first direction D1. Each of the first cell trenches 192T may be formed to penetrate the upper insulating layer 170 and an upper portion of the cell insulating layer 160. A bottom surface 192TL of each of the first cell trenches 192T may expose the top electrode TE of each of the corresponding ones of the data storage patterns DS.

Peripheral trenches 210T may be formed in the peripheral insulating layer 180 in the peripheral region PR. Each of the peripheral trenches 210T may be formed to penetrate an upper portion of the peripheral insulating layer 180 in the peripheral region PR. Peripheral holes 220H may be extended from bottom surfaces of the peripheral trenches 210T toward the substrate 100 in the third direction D3. In an embodiment, each of the peripheral holes 220H may be formed in the peripheral region PR to penetrate a lower portion of the peripheral insulating layer 180 and the first portions 120H and expose a top surface of a corresponding second conductive line of the uppermost conductive lines 102.

The first cell trenches 192T and the peripheral trenches 210T may be formed by a first etching process. In an embodiment, the first etching process may include forming a first mask pattern to define a region, in which the first cell trenches 192T and the peripheral trenches 210T will be formed, and etching the upper insulating layer 170, the cell insulating layer 160, and the peripheral insulating layer 180 using the first mask pattern as an etch mask. The first cell trenches 192T and the peripheral trenches 210T may be simultaneously formed by the first etching process.

Referring back to FIG. 2 and FIG. 3, first cell conductive lines 192 may be formed in the cell trenches 192T, respectively. Peripheral conductive lines 210 may be formed in the peripheral trenches 210T, respectively, and peripheral conductive contacts 220 may be formed in the peripheral holes 220H, respectively.

In an embodiment, the formation of the first cell conductive lines 192, the peripheral conductive lines 210, and the peripheral conductive contacts 220 may include forming a first conductive layer on the upper insulating layer 170 and the peripheral insulating layer 180 to fill the cell trenches 192T, the peripheral trenches 210T and the peripheral holes 220H and planarizing the first conductive layer to expose the top surface 170U of the upper insulating layer 170 and the top surface 180U of the peripheral insulating layer 180. Following the planarization process, the top surfaces 192U of the first cell conductive lines 192, the top surface 170U of the upper insulating layer 170, the top surface 180U of the peripheral insulating layer 180, and the top surfaces 210U of the peripheral conductive lines 210 may be located at the substantially same level.

A first interlayer insulating layer 230 may be formed in the cell region CR and the peripheral region PR to cover the top surface 170U of the upper insulating layer 170, the top surfaces 192U of the first cell conductive lines 192, the top surface 180U of the peripheral insulating layer 180, and the top surfaces 210U of the peripheral conductive lines 210.

Second cell conductive lines 196 and first conductive contacts 194 may be formed in the first interlayer insulating layer 230. In an embodiment, the formation of the second cell conductive lines 196 and the first conductive contacts 194 may include forming second cell trenches to penetrate an upper portion of the first interlayer insulating layer 230, forming first holes, which are extended from a bottom surface of each of the second cell trenches to penetrate a lower portion of the first interlayer insulating layer 230, forming a second conductive layer on the first interlayer insulating layer 230 to fill the second cell trenches and the first holes, and planarizing the second conductive layer to expose a top surface of the first interlayer insulating layer 230.

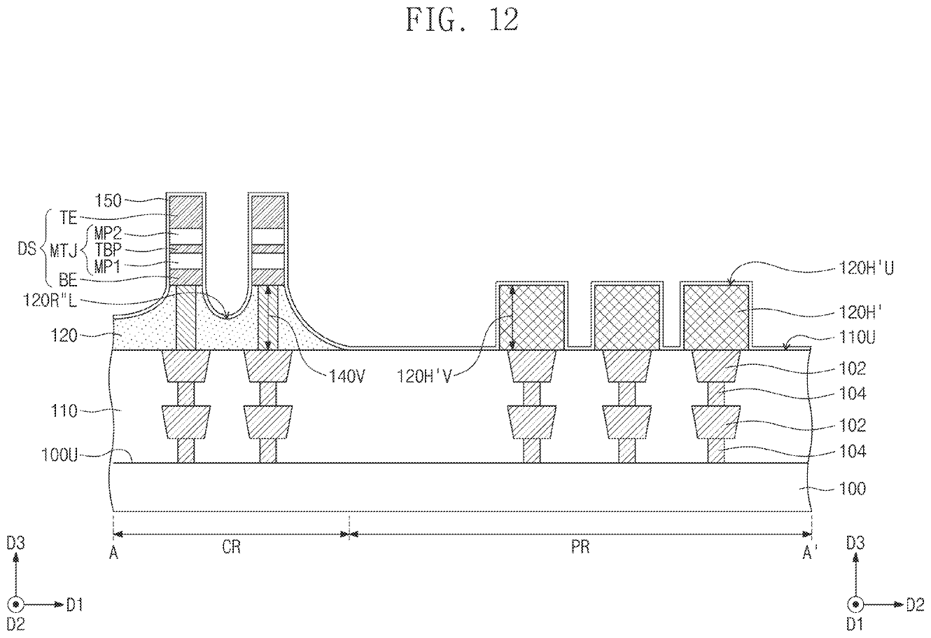

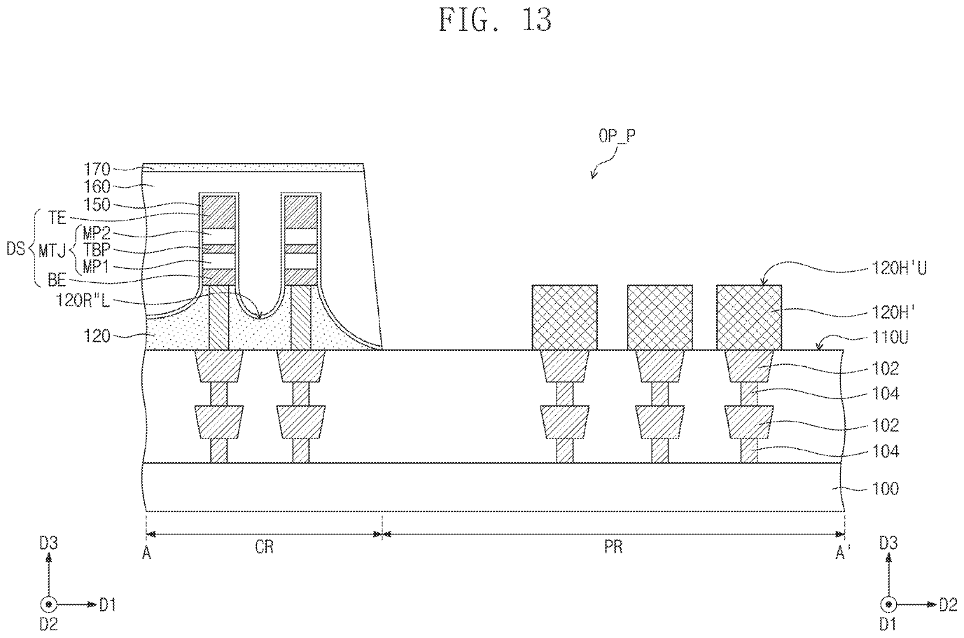

FIG. 10 is a sectional view taken along a line A-A′ of FIG. 2 to illustrate a magnetic memory device according to an embodiment of the inventive concept. For concise description, an element previously described with reference to FIG. 1, FIG. 2, FIG. 3, FIG. 4A, and FIG. 4B may be identified by the same reference number without repeating an overlapping description thereof.

Referring to FIG. 2 and FIG. 10, insulating patterns 120H′ may be disposed on the first insulating layer 110 in the peripheral region PR to cover top surfaces of corresponding ones of the conductive lines 102. The insulating patterns 120H′ may be disposed on the first insulating layer 110 in the peripheral region PR may entirely cover the top surfaces of corresponding ones of the conductive lines 102. For example, width 120H′_W of each of the insulating patterns 120H′ in the first direction D1 may be larger than or equal to a width 102_W of each of the conductive lines 102 in the first direction D1. In this case, the insulating patterns 120H′ may fully cover the conductive lines 102.

The insulating patterns 120H′ may have a crystal structure that is different from the second insulating layer 120 in the cell region CR. The insulating patterns 120H′ may include first and second nonmetals, which are different from those in the second insulating layer 120 in the cell region CR, and a bonding structure of the first and second nonmetals in the insulating patterns 120H′ may be different from a bonding structure of the first and second nonmetals in the second insulating layer 120 in the cell region CR. In an embodiment, the first and second nonmetals may be carbon and nitrogen, respectively, and a fraction of a sp³ C—N bonding in the insulating patterns 120H′ may be higher than a fraction of a sp³ C—N bonding in the second insulating layer 120 in the cell region CR.

The second insulating layer 120, which are formed between the data storage patterns DS in the cell region CR, may have a recess region that is recessed toward the substrate 100. The lowermost portion of the top surface 120R″L of the recess region of the second insulating layer 120 may be located at a level lower than a top surface 120H′U of the insulating patterns 120H′.

The bottom electrode contacts 140 may be disposed in the second insulating layer 120 in the cell region CR. The bottom electrode contacts 140 may be disposed below and electrically connected to the data storage patterns DS, respectively. Each of the bottom electrode contacts 140 may penetrate the second insulating layer 120 in the cell region CR and may be connected to a corresponding first conductive line of the uppermost conductive lines 102. The top surface 140U of the bottom electrode contacts may be located at a position higher than the lowermost portion of the top surface 120R″L of the recess region of the second insulating layer. The height 140V of the bottom electrode contacts 140 may be equal to a height or thickness 120H′V of the insulating patterns 120H′. In a case where the height 140V of the bottom electrode contacts 140 is reduced to the height or thickness 120H′V of the insulating patterns 120H′, it may be possible to increase an integration density of the magnetic memory device.

A peripheral insulating layer 180 may be disposed on the first insulating layer 110 in the peripheral region PR between the insulating patterns 120H′. The peripheral insulating layer 180 may be disposed on the first insulating layer 110 in the peripheral region PR to fill a space between the insulating patterns 120H′. The peripheral insulating layer 180 may be formed of, or include a material whose dielectric constant (k) may be less than the second insulating layer 120 and the insulating patterns 120H′. The peripheral insulating layer 180 may be formed of, or include at least one of silicon oxide, silicon nitride, and/or silicon oxynitride. As an example, the peripheral insulating layer 180 may include an insulating material (e.g., porous SiOC) whose dielectric constant (k) may be less than about 2.5 or 2.0. In a case where a space between the insulating patterns 120H′ is filled with the peripheral insulating layer 180, which may be formed of an insulating material of a low dielectric constant (k), it may be possible to increase a transfer speed of electric signals in the magnetic memory device. Thus, the magnetic memory device with improved electrical characteristics may be provided.

The peripheral conductive lines 210 may be disposed on the insulating patterns 120H′ and in the peripheral insulating layer 180. The peripheral insulating layer 180 may cover the peripheral conductive lines 210.

Peripheral conductive contacts 220 may be disposed in the peripheral region PR and under the peripheral conductive lines 210. The peripheral conductive contacts 220 may be electrically connected to the peripheral conductive lines 210. Each of the peripheral conductive contacts 220 may be in contact with a corresponding peripheral conductive line of the peripheral conductive lines 210 without any interface therebetween. The peripheral conductive contacts 220 and the corresponding peripheral conductive line 210 may be connected to each other to form a single object. Each of the peripheral conductive contacts 220 may be provided to penetrate a lower portion of the peripheral insulating layer 180. Each of the peripheral conductive contacts 220 may be provided to penetrate the insulating patterns 120H′ in the peripheral region PR and may be electrically connected to a corresponding second conductive line of the uppermost conductive lines 102.

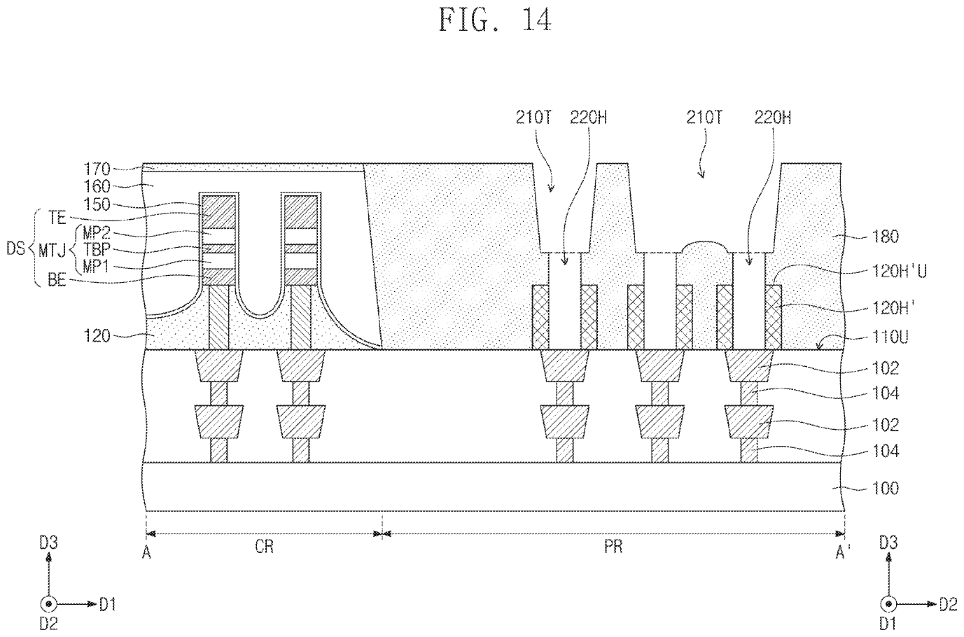

FIG. 11, FIG. 12, FIG. 13, and FIG. 14 are sectional views taken along the line A-A′ of FIG. 2 to illustrate a method of fabricating a magnetic memory device according to an embodiment of the inventive concept. For the sake of brevity, an element previously described with reference to FIG. 1, FIG. 2, FIG. 3, FIG. 4A, FIG. 4B, FIG. 5, FIG. 6, FIG. 7, FIG. 8, and FIG. 9 may be identified by the same reference number without repeating an overlapping description thereof.

Referring to FIG. 2 and FIG. 11, the second insulating layer 120 may be formed on the first insulating layer 110 to cover exposed top surfaces of the uppermost conductive lines 102. The second insulating layer 120 may be formed on the first insulating layer 110 in the cell region CR and may be extended to cover the first insulating layer 110 in the peripheral region PR. In the peripheral region PR, the second insulating layer 120 may include the insulating patterns 120H′, which are provided to cover top surfaces of the conductive lines 102 in the peripheral region PR. The formation of the insulating patterns 120H′ may include forming a mask pattern 121 on the second insulating layer 120 and irradiating an electron beam 122 onto the mask pattern 121. In an embodiment, the electron beam 122 may be an ion beam or a pulsed electron beam, and the mask pattern 121 may be a photoresist pattern. The insulating patterns 120H′, which are irradiated with the electron beam 122, may have a crystal structure different from the second insulating layer 120, which are not irradiated with the electron beam. As an example, the fraction of the sp³ C—N bonding in the insulating patterns 120H′ may be greater than the fraction of the sp³ C—N bonding in the second insulating layer 120. In a case where a width 120H′_W of the insulating patterns 120H′ in the first direction D1 is greater than or equal to a width 102_W of the conductive lines 102 in the first direction D1, the insulating patterns 120H′ may be provided to fully cover the conductive lines 102.

Referring to FIG. 2 and FIG. 12, each of the data storage patterns DS may include the bottom electrode BE, the magnetic tunnel junction MTJ, and the top electrode TE, which are sequentially stacked on the second insulating layer 120. In an embodiment, the formation of the data storage patterns DS may include sequentially forming a bottom electrode layer and a magnetic tunnel junction layer on the second insulating layer 120, forming a conductive mask pattern on the magnetic tunnel junction layer, and sequentially etching the magnetic tunnel junction layer and the bottom electrode layer using the conductive mask pattern as an etch mask. The magnetic tunnel junction layer may include a first magnetic layer, a tunnel barrier layer, and a second magnetic layer, which are sequentially stacked on the bottom electrode layer. In an embodiment, the magnetic tunnel junction layer and the bottom electrode layer may be formed by a sputtering, chemical vapor deposition, or atomic layer deposition process.

Following the etching of the magnetic tunnel junction layer and the bottom electrode layer, the magnetic tunnel junction MTJ and the bottom electrode BE may be formed, respectively. The etching of the magnetic tunnel junction layer may include sequentially etching the second magnetic layer, the tunnel barrier layer, and the first magnetic layer using the conductive mask pattern as an etch mask. The second magnetic layer, the tunnel barrier layer, and the first magnetic layer may be etched to form the second magnetic pattern MP2, the tunnel barrier pattern TBP, and the first magnetic pattern MP1, respectively. A portion of the conductive mask pattern remaining on the magnetic tunnel junction MTJ after the etching of the magnetic tunnel junction layer and the bottom electrode layer, may be referred to as the top electrode TE.

In an embodiment, the process of etching the magnetic tunnel junction layer and the bottom electrode layer may be an ion beam etching process performed using an ion beam. The ion beam may include inert ions. Following the etching process, the second insulating layer 120 may have a recess region, which may be recessed toward the substrate 100, between the data storage patterns DS. The lowermost portion of the top surface 120R″L of the recess region may be located at a level lower than the top surfaces 120H′U of the insulating patterns 120H′.

In addition, the second insulating layer 120 between the insulating patterns 120H′ may be removed by the etching process. With a high sp³ C—N bonding fraction, the insulating pattern 120H′ may have a hardness that is greater than the second insulating layer 120 in the peripheral region PR and may be hardly removed by the etching process. Thus, the insulating patterns 120H′ may be used to protect the conductive lines 102 in the peripheral region PR, reducing or preventing damage caused by the etching process. Accordingly, it may be possible to reduce a failure rate in a process of fabricating a magnetic memory device. Furthermore, the insulating patterns 120H′ may prevent the conductive lines 102 from being damaged by the etching process, and the height 140V of the bottom electrode contacts 140 may be reduced to the height or thickness 120H′V of the insulating patterns. Thus, it may be possible to easily increase an integration density of the magnetic memory device.

A capping insulating layer 150 may be formed on the second insulating layer 120 in the cell region CR to conformally cover top and side surfaces of each of the data storage patterns DS. The capping insulating layer 150 may conformally cover the lowermost portion of the top surface 120R″L of the recess region in the cell region CR and may cover a top surface 110U of the first insulating layer and the top surface 120H′U of the insulating patterns in the peripheral region PR.

Referring to FIG. 2 and FIG. 13, a peripheral opening OP_P may be formed in the peripheral region PR to expose the top surface 120H′U of the insulating patterns 120H′ and the top surface 110U of the first insulating layer 110 in the peripheral region PR. The formation of the peripheral opening OP_P may include removing the upper insulating layer 170, the cell insulating layer 160, and the capping insulating layer 150 from the peripheral region PR. In an embodiment, the formation of the peripheral opening OP_P may include forming a cell mask pattern on the upper insulating layer 170 in the cell region CR and etching the upper insulating layer 170, the cell insulating layer 160, and the capping insulating layer 150 in the peripheral region PR using the cell mask pattern as an etch mask. In an embodiment, the cell mask pattern may be a photoresist pattern. In a case where the upper insulating layer 170, the cell insulating layer 160, and the capping insulating layer 150 are removed from the peripheral region PR, a top surface 120′HU of the insulating patterns 120H′ and the top surface 110U of the first insulating layer 110 in the peripheral region PR may be exposed to the outside.

Referring to FIG. 2 and FIG. 14, a peripheral insulating layer 180 may be formed to fill the peripheral opening OP_P. The peripheral insulating layer 180 may be in contact with the top surface 110U of the first insulating layer 110 and the top surface 120H′U of the insulating pattern 120H′ in the peripheral region PR. The peripheral insulating layer 180 may be formed of, or include an insulating material whose dielectric constant may be lower than a dielectric constant of the cell insulating layer 160 and a dielectric constant of the upper insulating layer 170. In an embodiment, the formation of the peripheral insulating layer 180 may include forming an insulating layer to fill the peripheral opening OP_P and planarizing the insulating layer to expose a top surface of the upper insulating layer 170. In an embodiment, the insulating layer may be formed using, for example, a chemical vapor deposition process. The planarization process may be performed using at least one of an etch-back process or a chemical mechanical polishing process. In a case where a space between the insulating patterns 120H′ is filled with the peripheral insulating layer 180 with a low dielectric constant, it may be possible to increase a transfer speed of electric signals in the magnetic memory device. Thus, the magnetic memory device may be provided to have improved electrical characteristics.

Peripheral trenches 210T may be formed in the peripheral insulating layer 180 in the peripheral region PR. Each of the peripheral trenches 210T may be formed to penetrate an upper portion of the peripheral insulating layer 180 in the peripheral region PR. Peripheral holes 220H may be extended from bottom surfaces of the peripheral trenches 210T toward the substrate 100 in the third direction D3. Each of the peripheral holes 220H may be formed to penetrate a lower portion of the peripheral insulating layer 180 in the peripheral region PR and the insulating patterns 120H′ in the peripheral region PR and expose a top surface of a corresponding second conductive line of the uppermost conductive lines 102.

While example embodiments of the inventive concept have been particularly shown and described, it will be understood by one of ordinary skill in the art that variations in form and detail may be made therein without departing from the spirit and scope of the attached claims.

What is claimed is:

1. A magnetic memory device, comprising:
a plurality of conductive lines provided in a cell region and a peripheral region;
a first insulating layer provided in the cell region and the peripheral region, and surrounding the plurality of conductive lines;
a second insulating layer provided on the first insulating layer in the cell region and the peripheral region, and on top surfaces of the plurality of conductive lines; and
a plurality of data storage patterns provided on the second insulating layer in the cell region and electrically connected to corresponding first conductive lines of the plurality of conductive lines,
wherein the second insulating layer in the peripheral region comprises a plurality of first portions on the top surfaces of corresponding second conductive lines of the plurality of conductive lines, and a plurality of second portions disposed between the plurality of first portions, and
top surfaces of the plurality of first portions are disposed at a level higher than top surfaces of the plurality of second portions.

2. The magnetic memory device of claim 1, further comprising a substrate provided in the cell region and the peripheral region,
wherein the first insulating layer is provided on the substrate,
the cell region and the peripheral region of the substrate extend in a first direction that is parallel to a top surface of the substrate, and
a width of the plurality of first portions in the first direction is greater than or equal to a width of the plurality of conductive lines in the first direction.

3. The magnetic memory device of claim 1, further comprising a plurality of bottom electrode contacts provided between the plurality of data storage patterns and the plurality of conductive lines,
wherein the plurality of bottom electrode contacts are connected to the plurality of data storage patterns, respectively,
each of the plurality of bottom electrode contacts is connected to a corresponding conductive line of the first conductive lines, and
a height of the plurality of bottom electrode contacts is equal to a vertical thickness of the plurality of first portions.

4. The magnetic memory device of claim 3, further comprising a plurality of first cell conductive lines, which are disposed on the plurality of data storage patterns and are connected to the plurality of data storage patterns.

5. The magnetic memory device of claim 1, wherein the second insulating layer in the peripheral region has a first recess region, which is recessed toward the first insulating layer between the plurality of first portions.

6. The magnetic memory device of claim 5, further comprising a peripheral insulating layer provided on the second insulating layer in the peripheral region,
wherein the peripheral insulating layer fills the first recess region, and
the peripheral insulating layer has a dielectric constant less than the second insulating layer.

7. The magnetic memory device of claim 1, wherein the plurality of first portions have different crystal structures from the plurality of second portions.

8. The magnetic memory device of claim 1, wherein the second insulating layer comprises a carbon nitride (CN), and
a fraction of a sp³ C—N bonding in the plurality of first portions is greater than a fraction of a sp³ C—N bonding in the plurality of second portions.

9. The magnetic memory device of claim 3, wherein the second insulating layer in the cell region has a second recess region, which is recessed toward the first insulating layer between the plurality of data storage patterns, and
a lowermost portion of a top surface of the second recess region is located at a level lower than a top surface of the plurality of bottom electrode contacts.

10. The magnetic memory device of claim 1, further comprising a plurality of peripheral conductive lines provided on the first insulating layer in the peripheral region,
wherein each of the plurality of peripheral conductive lines penetrates the first portion and is connected to a corresponding conductive contact of the second conductive contacts.

11. A magnetic memory device, comprising:
a substrate including a cell region and a peripheral region;
a plurality of conductive lines provided in the cell region and the peripheral region of the substrate;
a first insulating layer provided on the substrate in the cell region and the peripheral region, and surrounding the conductive lines;
a second insulating layer disposed on the first insulating layer in the cell region to cover top surfaces of corresponding first conductive lines of the plurality of conductive lines;
a plurality of data storage patterns disposed on the second insulating layer in the cell region and electrically connected to the corresponding first conductive lines;
a plurality of insulating patterns disposed on the first insulating layer in the peripheral region on top surfaces of corresponding second conductive lines of the plurality of conductive lines; and
a peripheral insulating layer disposed on the first insulating layer in the peripheral region and between the plurality of insulating patterns,
wherein the peripheral insulating layer has dielectric constant lower than a dielectric constant of the second insulating layer and a dielectric constant of the plurality of insulating patterns.

12. The magnetic memory device of claim 11, wherein the plurality of insulating patterns and the second insulating layer have different crystal structures from each other.

13. The magnetic memory device of claim 12, wherein the second insulating layer and the plurality of insulating patterns comprise a carbon nitride (CN), and
a fraction of a sp³ C—N crystal in the plurality of insulating patterns is greater than a fraction of a sp³ C—N crystal in the second insulating layer.

14. The magnetic memory device of claim 11, wherein a width of each of the plurality of insulating patterns in a first direction is greater than or equal to a width of each of the plurality of conductive lines in the first direction, and
the first direction is parallel to a top surface of the substrate.

15. The magnetic memory device of claim 11, further comprising a plurality of bottom electrode contacts disposed between the plurality of data storage patterns and the plurality of conductive lines,
wherein the plurality of bottom electrode contacts are connected to the plurality of data storage patterns, respectively,
each bottom electrode contact of the plurality of bottom electrode contacts is connected to a corresponding conductive line of the plurality of conductive lines, and
a height of the plurality of bottom electrode contacts is equal to a height of the plurality of insulating patterns.

16. The magnetic memory device of claim 11, wherein the second insulating layer has a recess region, which is disposed between the plurality of data storage patterns and is recessed toward the substrate, and
a lowermost portion of a top surface of the recess region of the second insulating layer is located at a level lower than top surfaces of the plurality of insulating patterns.

17. A magnetic memory device, comprising:
a substrate including a cell region and a peripheral region;
a plurality of conductive lines provided in the cell region and the peripheral region of the substrate;
a first insulating layer provided on the substrate in the cell region and the peripheral region, surrounding the plurality of conductive lines;
a second insulating layer disposed on the first insulating layer in the cell region and the peripheral region to cover top surfaces of the plurality of conductive lines; and
a plurality of data storage patterns disposed on the second insulating layer in the cell region and electrically connected to corresponding conductive lines of the plurality of conductive lines,
wherein the second insulating layer in the peripheral region comprises a first portion covering top surfaces of the plurality of conductive lines in the peripheral region, and
the plurality of first portions have a crystal structure different from a crystal structure of the second insulating layer in the cell region.

18. The magnetic memory device of claim 17, wherein a width of the plurality of first portions in a first direction is greater than or equal to a width of the plurality of conductive lines in the first direction, and
the first direction is parallel to a top surface of the substrate.

19. The magnetic memory device of claim 17, further comprising a plurality of bottom electrode contacts disposed between the plurality of data storage patterns and the plurality of conductive lines,
wherein the plurality of bottom electrode contacts are connected to the plurality of data storage patterns, respectively,
each of the plurality of bottom electrode contacts is connected to a corresponding first conductive line of the plurality of conductive lines, and
a height of the plurality of bottom electrode contacts is equal to a vertical thickness of the first portion.

20. The magnetic memory device of claim 17, wherein the second insulating layer in the peripheral region has a recess region, which is disposed between the first portions and is recessed toward the substrate, and
a lowermost portion of a top surface of the recess region is located at a level lower than top surfaces of the first portions.
